(19) United States
(12) Patent Application Publication
(10) Pub. No.: US 2025/0211244 A1
(43) Pub. Date: Jun. 26, 2025

(54) TRIMMING PROCEDURE AND CODE REUSE FOR HIGHLY PRECISE DC-DC CONVERTERS

(71) Applicant: STMicroelectronics S.r.l., Agrate Brianza (MB) (IT)

(72) Inventors: Marco ATTANASIO, Olbia-Tempio (IT); Stefano RAMORINI, Milano (IT)

(73) Assignee: STMicroelectronics S.r.l., Agrate Brianza (MB) (IT)

(21) Appl. No.: 19/074,706

(22) Filed: Mar. 10, 2025

Related U.S. Application Data
(63) Continuation of application No. 17/980,188, filed on Nov. 3, 2022, now Pat. No. 12,267,084.

(51) Int. Cl. H03M 1/10; H02M 1/00; H03M 1/78

(52) U.S. Cl. CPC H03M 1/1057; H02M 1/0025; H03M 1/785

(57) ABSTRACT

A voltage conversion system provides gain and offset trimming for generating a controlled output voltage. The system includes a digital-to-analog converter (DAC) that generates a reference voltage based on an input code, and a voltage converter that converts an input voltage to an output voltage based on the reference voltage. A first adjustable reference circuit provides a first reference signal to the DAC and a second adjustable reference circuit provides a second reference signal to the DAC. Control circuitry adjusts the first adjustable reference circuit to perform gain trimming of the output voltage and adjusts the second adjustable reference circuit to perform offset trimming of the output voltage. A calibration procedure includes adjusting for both gain and offset, with a two-step approach for positive offset conditions—first incrementing the input code to create a negative offset, then performing offset trimming.

### RELATED APPLICATION

This application is a continuation of U.S. patent application Ser. No. 17/980,188, filed Nov. 3, 2022, the contents of which are incorporated by reference in their entirety.

### TECHNICAL FIELD

This disclosure is directed to the field of DC-DC converters and, in particular, to circuitry and calibration procedures for generating a highly precise reference voltage for use in the feedback loop of a DC-DC converter to provide that DC-DC converter with a high degree of precision in the generated DC output voltage, as well as procedures to provide that DC-DC converter with an extended voltage range.

### BACKGROUND

Now described with reference to FIG. 1A is a DC-DC converter system 5 that includes a DC-DC converter circuit 6 that converts an input DC voltage DC_{IN} to an output DC voltage DC_{OUT}. A feedback loop for the DC-DC converter circuit 6 includes resistors R2 and R1 series connected between the output of the DC-DC converter circuit 6 and a reference voltage VDO. A feedback voltage VFBK is generated at the tap between resistors R2 and R1 and is used by the DC-DC converter circuit 6 in regulating its output DC voltage DC_{OUT}. The reference voltage VDO is generated by a digital-to-analog converter (DAC) 7 based upon a reference voltage REF_DAC and an n-bit input code CODEn. As should be appreciated, through the adjustment of the value of VDO by the DAC 7, since the value of VFBK is fixed by the negative feedback, the value of the output DC voltage DC_{OUT} is adjusted.

An ideal example output range of the output DC voltage DC_{OUT} of the DC-DC converter 6 is shown in FIG. 1B. As can be observed in this example, the output DC voltage DC_{OUT} ideally ranges from −0.8V when the input code CODEn is at its minimum value to −6.6V when the input code CODEn is at its maximum value. However, real world components are not ideal. Indeed, error in the generation of the reference voltage REF_DAC or in the values of the resistors R1 and R2 results in gain error at multiple ones of the DAC steps (a single increment in CODEn being a DAC step); this may be observed in FIG. 1C, in which two possible instances of error are possible (e.g., the slope of the output DC voltage DC_{OUT} between the minimum value of CODEn and the maximum value of CODEn being such that the output DC voltage DC_{OUT} is above or below the desired value of −6.6V when CODEn is at its maximum value). Error in the DAC 7 or within feedback circuitry within the DC/DC converter circuit 6 results in the introduction of an offset; this may be observed in FIG. 1D, in which the curve of the output DC voltage DC_{OUT} is shifted downwardly such that when CODEn is at its minimum value the output DC voltage DC_{OUT} is less than −0.8V, and such that when CODEn is at its maximum value the output DC voltage DC_{OUT} is less than −6.6V.

To avoid gain error (FIG. 1C) and offset error (FIG. 1D), further development is needed.

### SUMMARY

A voltage conversion system with trimming capability, including a digital-to-analog converter (DAC) configured to generate a reference voltage based on an input code; a voltage converter configured to generate an output voltage based on an input voltage and the reference voltage; a first adjustable reference circuit coupled to the DAC and configured to provide a first reference signal to the DAC; a second adjustable reference circuit coupled to the DAC and configured to provide a second reference signal to the DAC; and control circuitry configured to adjust the first adjustable reference circuit to perform gain trimming of the output voltage and adjust the second adjustable reference circuit to perform offset trimming of the output voltage.

The first adjustable reference circuit may include a resistive network with multiple selectable taps.

The control circuitry may adjust the first adjustable reference circuit by selecting among the multiple selectable taps to set a resistance value.

The second adjustable reference circuit may include a resistive network with multiple selectable taps.

The DAC may include a resistive ladder network coupled to the second reference signal.

The control circuitry may be configured to perform a calibration procedure by adjusting the first adjustable reference circuit until the output voltage reaches a desired voltage range and adjusting the second adjustable reference circuit until the output voltage reaches a desired offset.

The calibration procedure may further include, when the output voltage reaches a positive offset relative to a given offset, adjusting the input code to create a negative offset and adjusting the second adjustable reference circuit until the output voltage reaches the desired offset.

The voltage conversion system may further include a feedback circuit coupled between an output of the voltage converter and the voltage converter, wherein the feedback circuit generates a feedback signal based on the output voltage and the reference voltage.

The first adjustable reference circuit may be adjustable to provide multiple operating ranges for the output voltage.

The voltage conversion system may further include a buffer circuit coupled between the DAC and the voltage converter, the buffer circuit configured to buffer the reference voltage.

A method for trimming voltage output in a voltage conversion system, including generating a first reference signal; generating a second reference signal based on the first reference signal; generating a digital-to-analog converter (DAC) output based on an input code and the second reference signal; converting an input voltage to an output voltage based on the DAC output; performing gain trimming of the output voltage by adjusting the first reference signal; and performing offset trimming of the output voltage by adjusting the second reference signal.

Performing gain trimming may include selecting a tap point in a first resistive network to adjust the first reference signal.

Performing offset trimming may include selecting a tap point in a second resistive network to adjust the second reference signal.

The method may further include determining whether the output voltage has a desired voltage range and adjusting the first reference signal until the output voltage is within the desired voltage range.

The method may further include determining whether the output voltage has a negative offset or a positive offset relative to a desired offset; when the output voltage has a negative offset, adjusting the second reference signal until the output voltage reaches the desired offset; and when the output voltage has a positive offset, adjusting the input code to create a negative offset and adjusting the second reference signal until the output voltage reaches the desired offset.

The method may further include generating a feedback signal based on the output voltage and providing the feedback signal to control the converting step.

The method may further include storing multiple settings for the first reference signal to enable selection between multiple operating ranges for the output voltage.

Generating the DAC output may include using a resistive ladder network coupled to the second reference signal.

The method may further include buffering the DAC output before using it in the converting step.

The method may further include performing a calibration procedure including the gain trimming and the offset trimming to achieve a desired output voltage characteristic.

### BRIEF DESCRIPTION OF THE DRAWINGS

FIG. 1A is a block diagram of a prior art DC-DC converter system.

FIG. 1B is a graph showing the output voltage of the DC-DC converter system of FIG. 1A in an ideal case.

FIG. 1C is a graph showing the output voltage of the DC-DC converter system of FIG. 1A in a real case in which gain error occurs.

FIG. 1D is a graph showing the output voltage of the DC-DC converter system of FIG. 1A in a real case in which offset error occurs.

FIG. 2 is a schematic block diagram of a DC-DC converter system described herein which provides for adjustment/correction of both gain and offset.

FIG. 3 is a schematic diagram of the digital-to-analog converter (DAC) of FIG. 2.

FIG. 4 is a graph showing the output voltage of the DC-DC converter system of FIG. 2 when performing gain trimming.

FIG. 5 is a graph showing the output voltage of the DC-DC converter system of FIG. 2 when performing offset trimming.

FIG. 6A is a graph showing the output voltage of the DC-DC converter system of FIG. 2 in a calibration mode when performing offset trimming, after performing gain trimming, in a case where the output voltage originally had a negative offset.

FIG. 6B is a graph showing the output voltage of the DC-DC converter system of FIG. 2 in a calibration mode when performing offset trimming, after performing gain trimming, in a case where the output voltage originally had a positive offset.

FIG. 7 is a graph showing the output voltage of the DC-DC converter system of FIG. 2 in a further calibration mode in which the gain is extended beyond what would normally be possible given the number of DAC input code bits used.

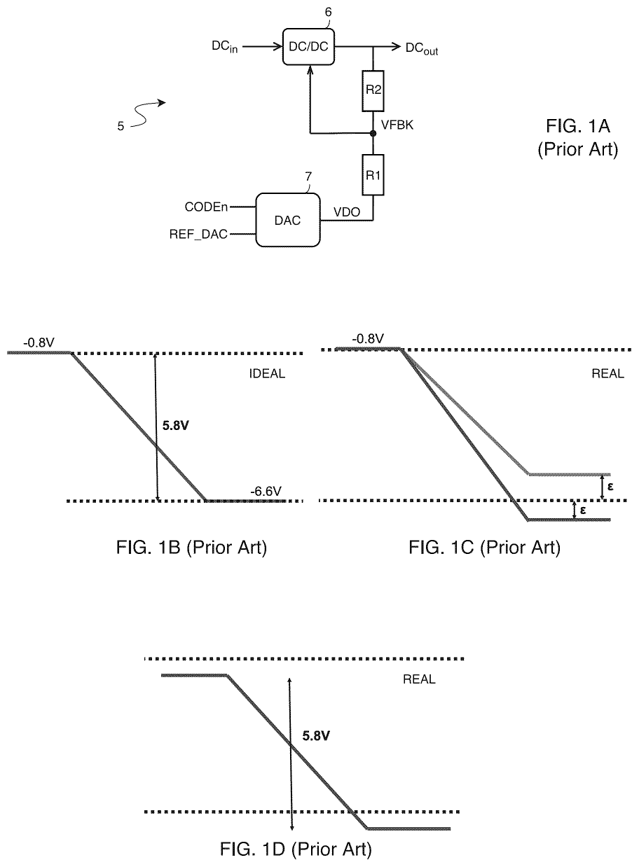

### DETAILED DESCRIPTION

The following disclosure enables a person skilled in the art to make and use the subject matter disclosed herein. The general principles described herein may be applied to embodiments and applications other than those detailed above without departing from the spirit and scope of this disclosure. This disclosure is not intended to be limited to the embodiments shown, but is to be accorded the widest scope consistent with the principles and features disclosed or suggested herein. Do note that in the below description, any described resistor or resistance is a discrete device unless the contrary is stated, and is not simply an electrical lead between two points. Thus, any described resistor or resistance coupled between two points has a greater resistance than a lead between those two points would have, and such resistor or resistance cannot be interpreted to be a lead. Similarly, any described capacitor or capacitance is a discrete device unless the contrary is stated, and is not a parasitic unless the contrary is stated. Moreover, any described inductor or inductance is a discrete device unless the contrary is stated, and is not a parasitic unless the contrary is stated. Furthermore, any “switch” described herein may be understood to be formed by one or more transistors of a suitable type.

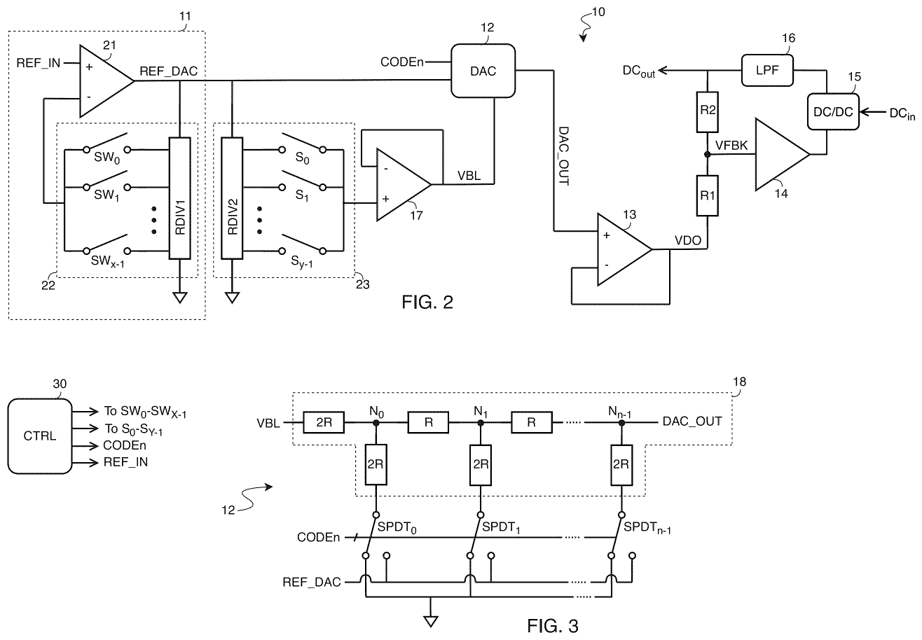

Now described with reference to FIG. 2 is a DC-DC converter system 10 described herein. The DC-DC converter system 10 includes a DC-DC converter circuit 15 that converts an input DC voltage DC_{IN} to an output DC voltage DC_{OUT}. A feedback loop for the DC-DC converter circuit 15 includes resistors R2 and R1 series connected between the output of the DC-DC converter circuit 15 (after passage through a low-pass filter 16) and a reference voltage VDO. A feedback voltage VFBK is generated at the tap between resistors R2 and R1, and is passed through an error amplifier 14 to be used by the DC-DC converter circuit 15 in regulating its output DC voltage DC_{OUT}. The reference voltage VDO is generated by a chain including a reference buffer 11 and a digital-to-analog converter (DAC) 12.

The reference buffer 11 is formed by a reference amplifier 21 having its non-inverting input terminal coupled to receive a reference input signal REF_IN and its inverting input terminal coupled to its output terminal through a resistive circuit 22. The resistive circuit includes X switches SW₀, . . . , SW_{X-1} each being connected between the inverting input terminal of the reference amplifier 21 and a different respective tap of a resistive ladder RDIV1, the resistive ladder RDIV1 being connected between the output of the reference amplifier 21 and ground. The reference buffer 11 serves to buffer the reference input signal REF_IN to produce a reference voltage REF_DAC at the output of the reference amplifier 21.

The DAC 12 may be of R-2R type, uses the reference voltage REF_DAC as its reference voltage, and generates a DAC output voltage DAC_OUT based upon an n-bit input code CODEn. The DAC 12 includes a R-2R ladder (shown in FIG. 3) connected between a tail reference voltage VBL and the output of the DAC 12. The tail reference voltage VBL is generated by the chain of a resistive circuit 23 and a tail reference buffer 17.

The buffer 17 is formed by an amplifier 17 that has its non-inverting input terminal connected to the resistive circuit 23 and its inverting input terminal connected to its output terminal, with the reference voltage VBL generated at its output. The resistive circuit 23 includes a resistive ladder RDIV2 connected between the output of the reference buffer 11 and ground, with Y switches S₀, . . . , S_{Y-1} each being connected between a different respective tap of a resistive ladder RDIV2 and the non-inverting input terminal of the amplifier 17.

A DAC buffer 13 serves to buffer the DAC output voltage DAC_OUT to produce the reference voltage VDO. The DAC buffer 13 is formed by an amplifier 13 having its non-inverting input terminal connected to the output of the DAC 12 to receive the DAC output voltage DAC_OUT and its inverting input terminal connected to its output, with the reference voltage VDO being produced at the output of the amplifier 13.

The DAC 12, as stated above, is of R-2R type, and is now described with additional reference to FIG. 3. The DAC 12 includes a R-2R resistor ladder 18 formed by n−1 resistors series connected between the reference voltage VBL and a final node Nₙ₋₁, with the DAC output voltage DAC_OUT being generated at the final node Nₙ₋₁. These n−1 resistors include a resistor 2R (having a resistance of 2·R) connected between the reference voltage VBL and node No, and then n−2 resistors R (each having a resistance of R), each being connected between different successive ones of the nodes N₀, . . . , Nₙ₋₁—for example, a resistor R connected between nodes N₀ and N₁, a resistor R connected between nodes N₁ and Nₙ₋₂, and so on. The R-2R resistor ladder 18 includes a different resistor R2 (each having a resistance of 2·R) connected between a corresponding one of the nodes N₀, . . . , Nₙ₋₁ and a respective one of the switches SPDT₀, . . . SPDTₙ₋₁.

The switches SPDT₀, . . . , SPDTₙ₋₁ each selectively connect their associated one of the resistors R2 to either ground or the reference voltage REF_DAC dependent upon a respective bit of the n-bit code CODEn. When a given bit of CODEn is at a logic low (e.g., 0), its associated switch SPDT₀, . . . , SPDTₙ₋₁ connects its 2R resistor to ground, and when a given bit of CODEn is at a logic high (e.g., 1), its associated switch SPDT₀, . . . , SPDTₙ₋₁ connects its 2R resistor to the reference voltage REF_DAC. By way of example, if the least significant bit of CODEn is at a logic low, switch SPDT₀ will connect its 2R resistor to ground, and if the least significant bit of CODEn is at a logic high, switch SPDT₀ will connect its 2R resistor to REF_DAC. As another example, if the most significant bit of CODEn is at a logic low, switch SPDTₙ₋₁ will connect its 2R resistor to ground, and if the most significant bit of CODEn is at a logic high, switch SPDTₙ₋₁ will connect its 2R resistor to REF_DAC.

Control circuitry 30 controls switches SW₀, . . . , SW_{X-1} and switches S₀, . . . , S_{Y-1}, and generates CODEn as well as REF_IN.

Operation is now described. First, the way in which the DC-DC converter system 10 provides for both gain and offset trimming (adjustment) will be described, and thereafter, calibration procedures for performing the gain and offset trimming will be described.

The changing of the feedback resistance connected between the inverting input terminal and output of the reference amplifier 21 through the closing of one or more of the switches SW₀, . . . , SW_{X-1}, under control of the control circuitry 30, serves to trim the gain—adjusts the slope of the output DC voltage DC_{OUT} between its minimum value and its maximum value with a final accuracy equal to approximately

$$\frac{STEP SIZE OF REF\_DAC}{REF\_DAC} \times \frac{100}{2} .$$

In detail, the maximum gain of the output DC voltage DC_{OUT} is dependent upon the number of bits n of the n-bit code CODEn, and may be calculated as:

$$GAIN = \frac{REF\_DAC}{{2}^{8}} \cdot \frac{R 2}{R 1}$$

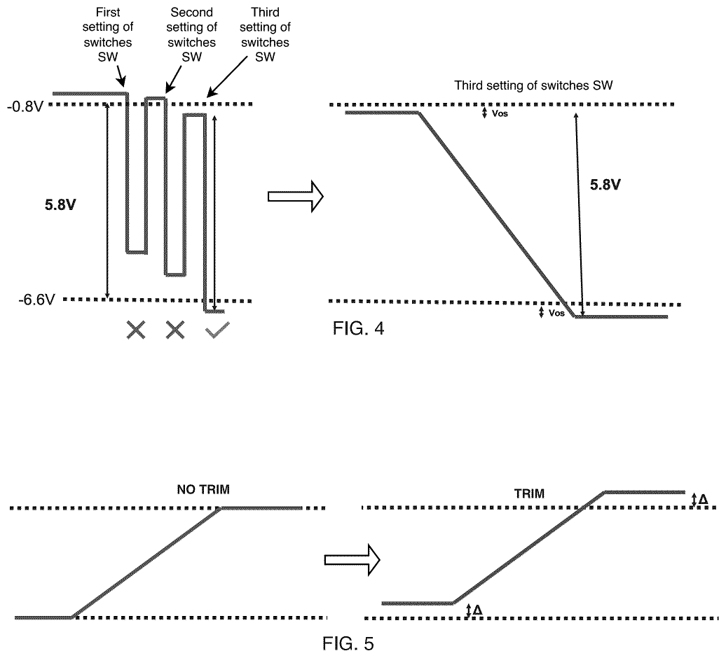

Since the trimming operation performed through changing of the feedback resistance connected between the inverting input terminal and output of the reference amplifier 21 through the closing of one or more of the switches SW₀, . . . , SW_{X-1}, under control of the control circuitry 30, ultimately changes the value of REF_DAC, and since the gain of the output DC voltage DC_{OUT} is dependent upon REF_DAC, gain control is therefore performed through the above described trimming. The effect of this gain adjustment accomplished through trimming can be seen in FIG. 4. The desired range between minimum and maximum value of the output DC voltage DC_{OUT} is 5.8V. With a first setting of the switches SW₀, . . . , SW_{X-1}, the desired range is not 5.8V; with a second setting of the switches SW₀, . . . , SW_{X-1}, the desired range is still not 5.8V; however, with a third setting of the switches SW₀, . . . , SW_{X-1}, the desired range of the output DC voltage DC_{OUT} is properly 5.8V as desired.

The changing of the input resistance to the non-inverting input terminal of the amplifier 17 through the closing of one or more of the switches S₀, . . . , S_{Y-1}, under control of the control circuitry 30, serves to change the reference voltage VBL and in turn trims the offset—adjusts the offset of the output DC voltage DC_{OUT} in its range between its minimum value and its maximum value. The effect of this offset adjustment can be seen in FIG. 5. Notice that the application of offset trimming does not change the range/slope of the output DC voltage DC_{OUT}, but does serve to shift the output DC voltage DC_{OUT} upward—the minimum and maximum voltages are each increased by the same amount A.

Through the adjustment of the value of the DAC output voltage DAC_OUT by the DAC 12, the value of VDO is adjusted, and in turn the value of the output DC voltage DC_{OUT} is adjusted. As explained, through the adjustment of the value of the voltage VBL, the offset of the output DC voltage DC_{OUT} is adjusted.

The potential step sizes in the values of the DAC output voltage DAC_OUT are dependent upon the number of bits n in the n-bit code CODEn. Namely, the steps may be as small as:

$$Δ {DAC}_{OUT} = VBL / {2}^{n} .$$

Given the above, the potential step sizes in the value of the offset applied to the output DC voltage DC_{OUT} are dependent upon the number of bits in n the n-bit code CODEn. These steps may be as small as:

$$Δ D {C}_{OUT} = \frac{VBL}{{2}^{n}} \cdot \frac{R 2}{R 1} .$$

With the above understanding of how gain and offset trimming of the output DC voltage DC_{OUT} is performed, procedures for performing the gain and offset trimming will now be described. In a calibration mode, the control circuitry 30 first performs gain trimming until the desired range between the minimum and maximum value of the output DC voltage DC_{OUT} is reached. This can be performed by iteratively incrementing or decrementing the X-bit control word applied to the switches SW₀, . . . , SW_{X-1}, such as shown in FIG. 4, until the desired range (gain) is reached.

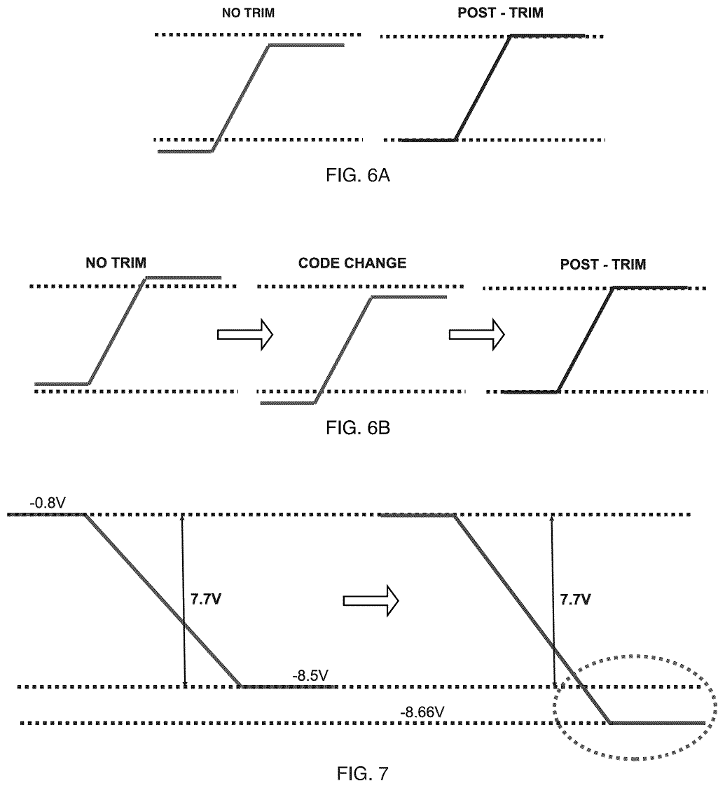

Next, offset trimming is performed. Two instances may occur. The first instance, shown in FIG. 6A, is where the output DC voltage DC_{OUT} has a negative offset prior to offset trimming; offset trimming, as described above is then performed by iteratively incrementing or decrementing the Y-bit control word applied to the switches S₀, . . . , S_{Y-1}, such as shown in FIG. 5, until the desired shift (offset) is reached.

The second instance, shown in FIG. 6B, is where the output DC voltage DC_{OUT} has a positive offset prior to offset trimming; here, the n-bit code CODEn is first incremented, which serves to shift the value of the DAC output voltage DAC_OUT upward, in turn shifting the output DC voltage DC_{OUT} downward. As a result of this, the output DC voltage DC_{OUT} now has a negative offset instead of a positive offset. Then, offset trimming, as described above, is performed. This completes the calibration mode, precisely trimming for both gain and offset.

Optionally, a further calibration may be performed to permit adjusting the range of the output DC voltage DC_{OUT} beyond what would be achievable for as given number n of the n-bit code CODEn. In order to do this, once the calibration described above is performed, REF_DAC is increased. This increase in REF_DAC serves to increase the individual step sizes during gain trimming, thereby increasing gain, as shown in FIG. 7—here, by increasing REF_DAC suitably, the range of the output DC voltage DC_{OUT} between its minimum value and its maximum value is increased from 7.7V to 7.86V. The value of REF_DAC that accomplishes the desired increase in the range of the output DC voltage DC_{OUT} may be stored in a register within the control circuitry 30 together with the initial value of REF_DAC, permitting switching between two different ranges of the output DC voltage DC_{OUT}. In fact, multiple different additional values of REF_DAC may be stored to permit selection between multiple different ranges of the output DC voltage DC_{OUT}.

Finally, it is clear that modifications and variations may be made to what has been described and illustrated herein, without thereby departing from the scope of this disclosure, as defined in the annexed claims.

While the disclosure has been described with respect to a limited number of embodiments, those skilled in the art, having benefit of this disclosure, will appreciate that other embodiments can be envisioned that do not depart from the scope of the disclosure as disclosed herein. Accordingly, the scope of the disclosure shall be limited only by the attached claims.

1. A voltage conversion system with trimming capability, comprising:
a digital-to-analog converter (DAC) configured to convert an input code to a reference voltage;
a voltage converter configured to generate an output voltage in response to an input voltage and the reference voltage;
a first adjustable reference circuit coupled to the DAC and configured to provide a first reference signal to the DAC;
a second adjustable reference circuit coupled to the DAC and configured to provide a second reference signal to the DAC; and
control circuitry configured to:
adjust the first adjustable reference circuit to perform gain trimming of the output voltage; and
adjust the second adjustable reference circuit to perform offset trimming of the output voltage.

2. The voltage conversion system of claim 1, wherein the first adjustable reference circuit comprises a resistive network with multiple selectable taps.

3. The voltage conversion system of claim 2, wherein the control circuitry sets a resistance value for adjusting the first adjustable reference circuit by selecting among the multiple selectable taps.

4. The voltage conversion system of claim 1, wherein the second adjustable reference circuit comprises a resistive network with multiple selectable taps.

5. The voltage conversion system of claim 1, wherein the DAC comprises a resistive ladder network coupled to the second reference signal.

6. The voltage conversion system of claim 1, wherein the control circuitry is configured to perform a calibration procedure by:
adjusting the first adjustable reference circuit until the output voltage reaches a desired voltage range; and
adjusting the second adjustable reference circuit until the output voltage reaches a desired offset.

7. The voltage conversion system of claim 6, wherein the calibration procedure further comprises, when the output voltage reaches a positive offset relative to a given offset:
adjusting the input code to create a negative offset; and
adjusting the second adjustable reference circuit until the output voltage reaches the desired offset.

8. The voltage conversion system of claim 1, further comprising a feedback circuit coupled between an output of the voltage converter and the voltage converter, wherein the feedback circuit generates a feedback signal in response to the output voltage and the reference voltage.

9. The voltage conversion system of claim 1, wherein the first adjustable reference circuit is adjustable to provide multiple operating ranges for the output voltage.

10. The voltage conversion system of claim 1, further comprising a buffer circuit coupled between the DAC and the voltage converter, the buffer circuit configured to buffer the reference voltage.

11. A method for trimming voltage output in a voltage conversion system, comprising:
generating a first reference signal;
generating a second reference signal in response to the first reference signal;
generating a digital-to-analog converter (DAC) output based on an input code and the second reference signal;
converting an input voltage to an output voltage based on the DAC output;
adjusting the first reference signal to perform gain trimming of the output voltage; and
adjusting the second reference signal to perform offset trimming of the output voltage.

12. The method of claim 11, wherein adjusting the first reference signal to perform gain trimming comprises selecting a tap point in a first resistive network.

13. The method of claim 11, wherein adjusting the second reference signal to perform offset trimming comprises selecting a tap point in a second resistive network.

14. The method of claim 11, further comprising:
determining whether the output voltage has a desired voltage range; and
adjusting the first reference signal until the output voltage is within the desired voltage range.

15. The method of claim 11, further comprising:
determining whether the output voltage has a negative offset or a positive offset relative to a desired offset;
when the output voltage has a negative offset, adjusting the second reference signal until the output voltage reaches the desired offset; and
when the output voltage has a positive offset:
adjusting the input code to create a negative offset; and
adjusting the second reference signal until the output voltage reaches the desired offset.

16. The method of claim 11, further comprising generating a feedback signal based on the output voltage and providing the feedback signal to control said converting the input voltage to the output voltage.

17. The method of claim 11, further comprising storing multiple settings for the first reference signal to enable selection between multiple operating ranges for the output voltage.

18. The method of claim 11, wherein generating the DAC output comprises using a resistive ladder network coupled to the second reference signal.

19. The method of claim 11, further comprising buffering the DAC output before using it in said converting the input voltage to the output voltage.

20. The method of claim 11, further comprising performing a calibration procedure comprising the gain trimming and the offset trimming to achieve a desired output voltage characteristic.
